(19) United States
(12) Patent Application Publication
(10) Pub. No.: US 2026/0353664 A1
(43) Pub. Date: Nov. 5, 2026

(54) NEUROMORPHIC FERROELECTRIC FIELD EFFECT TRANSISTOR (FEFET) DEVICE WITH ANTI-FERROELECTRIC BUFFER LAYER

(71) Applicant: TAIWAN SEMICONDUCTOR MANUFACTURING COMPANY, LTD., Hsinchu (TW)

(72) Inventors: Chao-I WU, Hsinchu (TW); Yu-Ming LIN, Hsinchu (TW)

(21) Appl. No.: 19/743,842

(22) Filed: Jul. 16, 2026

Related U.S. Application Data
(62) Division of application No. 17/721,814, filed on Apr. 15, 2022.
(60) Provisional application No. 63/211,705, filed on Jun. 17, 2021.

(51) Int. Cl. H10B 51/30; H10D 30/67; H10D 30/69; H10D 99/00

(52) U.S. Cl. CPC H10B 51/30; H10D 30/6739; H10D 30/6755; H10D 30/701; H10D 99/00

(57) ABSTRACT

A ferroelectric field effect transistor device includes a back gate structure over a substrate. The ferroelectric field effect transistor device includes a ferroelectric layer over the back gate structure. The ferroelectric field effect transistor device includes an anti-ferroelectric layer over the ferroelectric layer. The ferroelectric field effect transistor device includes a metal oxide channel over the anti-ferroelectric layer, the metal oxide channel comprising a multi-component oxide compound including at least one metal from group 12 and at least one metal from group 13. The ferroelectric field effect transistor device includes source/drain regions over the metal oxide channel.

### PRIORITY CLAIM

The present application is a divisional of U.S. application Ser. No. 17/721,814, filed Apr. 15, 2022, which claims the priority of U.S. Prov. Appl. No. 63/211,705, filed Jun. 17, 2021, which is incorporated herein by reference in their entireties.

### BACKGROUND

Semiconductor devices are used in a variety of electronic applications, such as personal computers, cell phones, digital cameras, and other electronic equipment. Semiconductor devices are fabricated by sequentially depositing insulating or dielectric layers, conductive layers, and semiconductor layers of material over a substrate, and patterning the various material layers using lithography to form circuit components and elements thereon. As the semiconductor industry has progressed into nanometer technology process nodes in pursuit of higher device density, higher performance, and lower costs, challenges from both fabrication and design issues have resulted in the development of three-dimensional designs.

The semiconductor integrated circuit (IC) industry has experienced rapid growth. Technological advances in IC materials and design have produced generations of ICs with each generation having smaller and more complex circuits than the previous generation. However, the semiconductor industry progression into nanometer technology process nodes has resulted in the development of three-dimensional designs including, for example, Fin Field Effect Transistor (FinFET), Gate-All-Around (GAA) devices, and Embedded Memory (EM) devices. In some instances, the EM devices are monolithically integrated with a host IC device, e.g., a Central Processing Unit (CPU) and are added during back end of line (BEOL) processing on the backside of the host IC device. In some instances, the EM applications include Ferroelectric Field Effect Transistors (FeFET) that are used in forming embedded Dynamic Random Access Memory (eDRAM) and/or Ferroelectric Random Access Memory (FeRAM) devices.

### BRIEF DESCRIPTION OF THE DRAWINGS

Aspects of the present disclosure are best understood from the following detailed description when read with the accompanying Figures. It is noted that, in accordance with the standard practice in the industry, various features are not drawn to scale. In fact, the dimensions of the various features may be arbitrarily increased or reduced for clarity of discussion.

FIGS. 1A and 1B are cross-sectional views of FeFET device structures according to some embodiments.

FIGS. 2A and 2B are graphs showing doping profiles of FeFET device structures according to some embodiments.

FIGS. 3A and 3B are graphs showing doping profiles of FeFET device structures according to some embodiments.

FIGS. 4A and 4B are cross-sectional views of FeFET device structures during a programming operation according to some embodiments.

FIGS. 5A and 5B are cross-sectional views of FeFET device structures during an erase operation according to some embodiments.

FIG. 6 is a schematic diagram of a system for manufacturing FeFET devices according to some embodiments.

FIG. 7 is a flowchart of IC device design, manufacture, and programming of IC devices according to some embodiments.

FIG. 8 is a schematic diagram of a processing system for manufacturing FeFET devices according to some embodiments.

FIG. 9 is a flowchart of manufacturing process suitable for the production of ferroelectric IC devices according to some embodiments.

FIGS. 10A-F are cross-sectional views during the manufacture of a ferroelectric IC device according to some embodiments.

### DETAILED DESCRIPTION

This description of the exemplary embodiments is intended to be read in connection with the accompanying drawings, which are to be considered part of the entire written description. The following disclosure provides many different embodiments, or examples, for implementing different features of the provided subject matter. The drawings are not to scale and the relative sizing and placement of structures have been modified for clarity rather than dimensional accuracy. Specific examples of components, values, operations, materials, arrangements, or the like, are described below to simplify the present disclosure.

These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “vertical,” “horizontal,” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The apparatus and structures may be otherwise oriented (rotated by, for example, 90°, 180°, or mirrored about a horizontal or vertical axis) and the spatially relative descriptors used herein may likewise be interpreted accordingly.

The structures and methods detailed below relate generally to the structures, designs, and manufacturing methods for IC devices, including ferroelectric field effect transistor (FeFET) devices that include at least one anti-ferroelectric layer adjacent a ferroelectric layer. The anti-ferroelectric layers improve the performance and reliability of the ferroelectric layer by providing a buffer layer between the ferroelectric layer and metal-containing layers including, for example, channel layers and gate electrode layers, for suppressing metal migration into the ferroelectric layer that would tend to degrade device performance. In some embodiments, the anti-ferroelectric layers provide a transition layer between the ferroelectric layer and adjacent layers, thereby providing a less abrupt composition change between the layers and/or suppressing formation of interface traps (electrically active defects located at the interface and capable of trapping and de-trapping charge carriers resulting in degraded device performance). Although the structures and methods will be discussed in terms of FeFET devices, the structures and methods are not so limited and are suitable for inclusion in manufacturing processes for other classes and configurations of IC devices.

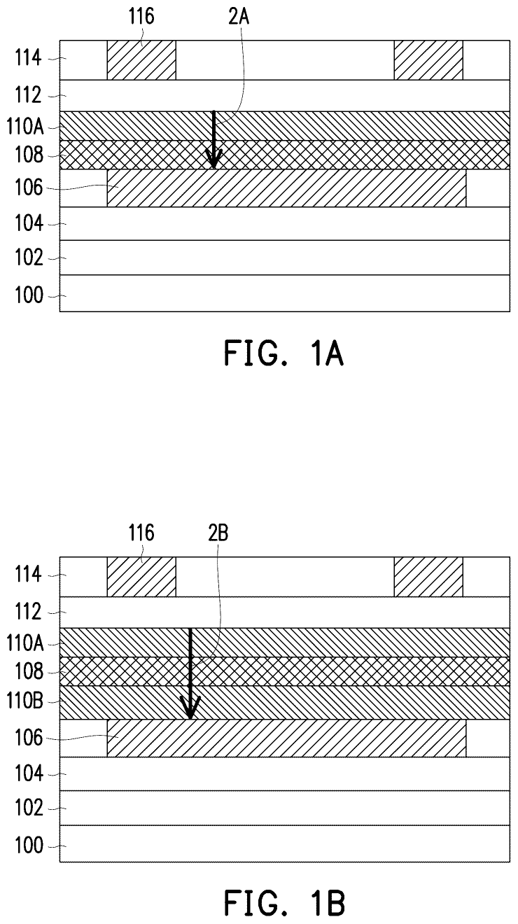

FIG. 1A is a cross-sectional view of a FeFET device structure according to some embodiments including a semiconductor substrate 100, a logic device region 102, and an insulating or dielectric layer 104. A back gate 106 is over the insulating layer 104 and a ferroelectric layer 108 (sometimes referred to as a memory layer) is over the back gate 106. A first or upper anti-ferroelectric layer 110A is over the ferroelectric layer 108. A metal oxide channel 112 is over the anti-ferroelectric layer 110A. A dielectric pattern 114 is over the metal oxide channel 112 and source/drain regions 116 are in openings in the dielectric pattern 114, with adjacent source/drain regions 116 being electrically separated by residual portions of the dielectric pattern 114.

In some embodiments, the metal oxide forming the metal oxide channel 112 includes at least one metal from group 12 (group IIB of the Chemical Abstract Service (CAS) table) and at least one metal from group 13 (group IIIA of the CAS table) to form a multi-component oxide compound including, for example, zinc-gallium oxide, cadmium-gallium oxide, and cadmium-indium oxide. In some embodiments, the multi-component oxide compound is present in an amorphous form, a single-phase crystalline state, or a mixed-phase crystalline state.

In some embodiments, the first or upper anti-ferroelectric layer 110A includes an ordered (crystalline) array of electric dipoles, resulting from the distribution of the ions and electrons in the material, but with most adjacent dipoles oriented in opposite (anti-parallel) directions so that the material exhibits a total, macroscopic spontaneous polarization of 0. In some embodiments, the anti-ferroelectric material comprises the same components as the ferroelectric material, described below, but includes the components in differing ratios, with the anti-ferroelectric material including a higher level of the dopant(s) than that found in the ferroelectric material, the higher level of the dopant(s) being sufficient to suppress ferroelectric activity in the resulting anti-ferroelectric compound.

The ferroelectric layer 108 is over the back gate 106 utilizing a material that exhibits ferroelectric properties associated with various materials having non-centrosymmetric crystalline structures. Ferroelectric materials suitable for use in manufacturing ICs in some embodiments include, for example, BaTiO3, Pb(Zr, Ti)O3 (PZT), SrBi2Ta2O9 (SBT), BiFeO3 (BFO), Bi0.5(Na0.80K0.20)0.5(Ti1−x Zr x)O3 (BNKT−xZr), and mixtures and combinations thereof. Other ferroelectric materials include Si-doped HfO2 and Si-doped HfZrO2. Unlike some of the other ferroelectric materials, the Hf-based ferroelectric materials tend to exhibit ferroelectricity with Pr (remnant polarization) values of 10 μC/cm2 or more for thin films that render such compositions useful in some thin-film applications.

In some embodiments, because similar or identical components are utilized in forming both the anti-ferroelectric layer(s) and the ferroelectric layer, the anti-ferroelectric layer(s) and the ferroelectric layer are formed in a single deposition process during which the ratio of the components being fed into the deposition chamber or reactor chamber is deliberately adjusted over the course of the process to produce layers having predetermined compositions that exhibit the ferroelectric and anti-ferroelectric properties designed for the intended functionality of the resulting IC device. By controlling the rate(s) at which the feed rates of the various components are changed over the course of the formation/deposition operation, in some embodiments there is a gradual change in the composition of the ferroelectric/anti-ferroelectric layers as they are being formed. In some embodiments, the rate(s) at which the feed rates produce a multi-step change in the composition of the ferroelectric/anti-ferroelectric layers as they are being formed. In some embodiments, the rate(s) at which the feed rates produce a single step change in the composition of the ferroelectric/anti-ferroelectric layers as they are being formed.

The back gate 106 includes any suitable conductor or combination of conductors and, in some embodiments, will include one or more of a seed layer, an adhesion layer, and/or a barrier layer formed adjacent the bulk of the conductor(s) comprising the back gate 106.

FIG. 1B is a cross-sectional view of a FeFET device structure according to some embodiments. The FeFET device in FIG. 1B is similar to the FeFET device in FIG. 1A and described above in which a second or lower anti-ferroelectric layer 110B is between the back gate 106 and the ferroelectric layer 108.

In some embodiments, the composition and the thickness of the first or upper anti-ferroelectric layer 110A and the composition and the thickness of the second or lower anti-ferroelectric layer 110B are substantially identical. In some embodiments, the composition of the first anti-ferroelectric layer 110A and the composition of the second anti-ferroelectric layer 110B are different. In some embodiments, the thickness of the first anti-ferroelectric layer 110A and the thickness of the second anti-ferroelectric layer 110B are different. In some embodiments, both the composition and the thickness of the first anti-ferroelectric layer 110A differ from the composition and the thickness of the second anti-ferroelectric layer 110B.

In some embodiments, the first anti-ferroelectric layer 110A has a thickness of about 0.1 nm to 1 nm. This thickness range provides sufficient protection against diffusion of metal from the metal oxide channel 112 into the ferroelectric layer 108 and/or suppresses trap formation at the interface between the layers. In some embodiments, the first anti-ferroelectric layer 110A is paired with a ferroelectric layer 108 having a thickness of about 8 nm to 10 nm, a thickness of ferroelectric material sufficient to provide a predetermined level of control over the device performance, specifically VT, after the ferroelectric layer is programmed to set the magnetic orientation of the incorporated material(s). In some embodiments, ratios of the first anti-ferroelectric layer 110A thickness and the ferroelectric layer 108 thickness ranges from about 1:100 to 1:8 while providing a predetermined level of anti-diffusion protection and programming response within the FeFET.

In some embodiments, the first anti-ferroelectric layer 110A has a thickness of about 1 nm to about 5 nm. This thickness range provides sufficient protection from diffusion of metal from the metal oxide channel 112 into the ferroelectric layer 108 and/or suppresses trap formation at the interface between the layers. In some embodiments, the first anti-ferroelectric layer 110A is paired is paired with a ferroelectric layer 108 having a thickness of about 5 nm to about 15 nm, a thickness of ferroelectric material sufficient to provide a predetermined level of control over the gate performance, specifically VT, after the ferroelectric layer is programmed to set the magnetic orientation of the incorporated material(s). In some embodiments, ratios of the first anti-ferroelectric layer 110A thickness and the ferroelectric layer 112 thickness ranges from about 1:15 to 1:1 while providing the predetermined level of anti-diffusion protection and programming response within the FeFET.

In some embodiments, the second anti-ferroelectric layer 110B has a thickness of about 0.1 nm to about 5 nm. This thickness range provides sufficient protection from diffusion from the later-formed back gate 106 and/or suppresses trap formation at the interface between the layers. In some embodiments, the second anti-ferroelectric layer 110B is paired with a ferroelectric layer 108 having a thickness of about 1 nm to about 15 nm, a thickness of ferroelectric material sufficient to provide a predetermined level of control over the gate performance, specifically VT, after programming. In some embodiments, ratios of the second anti-ferroelectric layer 110B thickness and the ferroelectric layer 108 thickness ranges from about 1:150 to 1:1 while providing the desired anti-diffusion effect and programming response within the FeFET.

In some embodiments, the first anti-ferroelectric layer 110A, the ferroelectric layer 108, and, if present, the second anti-ferroelectric layer 110B, include the same atomic components. The atomic/molar ratios of those atomic components, however, differ between the first and second anti-ferroelectric layers 110A, 110B and the ferroelectric layer 108 such that only the ferroelectric layer exhibits a spontaneous electric polarization that is able to be 1) induced by an external electric field produced by applying a programming voltage +Vg to the back gate 106, 2) maintained without application of a voltage to the back gate layer 106, and 3) erased by applying an erase voltage −Vg to the back gate layer 106.

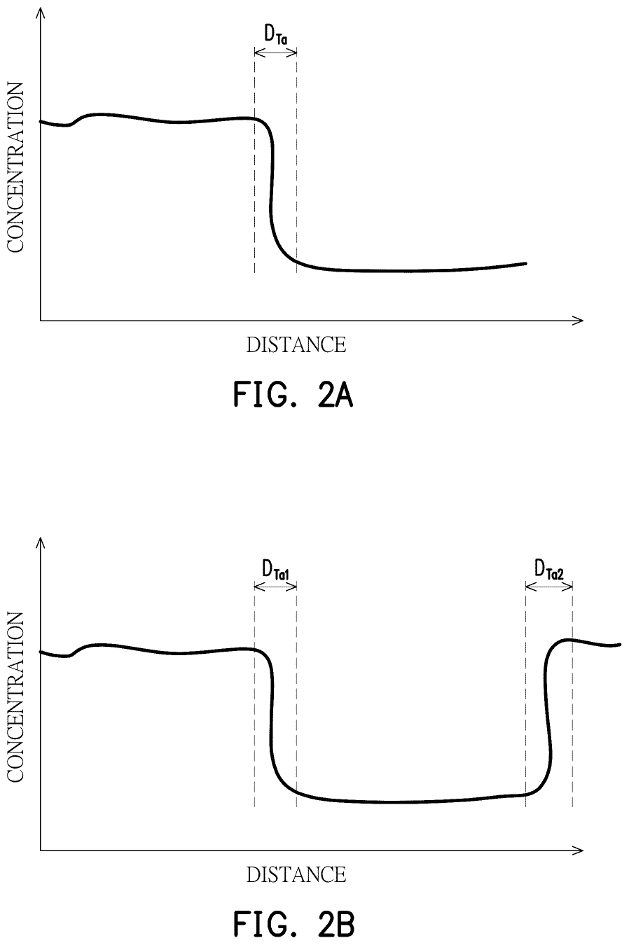

FIG. 2A is a graph of doping profiles of a FeFET device structure according to some embodiments according to FIG. 1A along the direction indicated by line 2A and crossing the interface between the first anti-ferroelectric layer 110A and the ferroelectric layer 108. In some embodiments, a difference in the doping levels for the composition of the first anti-ferroelectric layer 110A and the composition of the ferroelectric layer 108 is included in FIG. 2A. As noted above, although different, in some embodiments the compositions of the first anti-ferroelectric layer 110A and the ferroelectric layer 108 are generally consistent throughout the respective layers. In some embodiments, the change in composition is relatively abrupt with the concentration changing from that of the first anti-ferroelectric layer 110A to that of the ferroelectric layer 108 over a relatively short transition distance (DTa) that is less than the thickness of either of the first anti-ferroelectric layer 110A and the ferroelectric layer 108, for example, 0.01 nm to 0.1 nm, depending on the predetermined performance specifications/targets of the particular IC device and the associated design rule set.

FIG. 2B is a graph of doping profiles of a FeFET device structure according to some embodiments according to FIG. 1B along the direction indicated by line 2B and crossing both a first interface between the first anti-ferroelectric layer 110A and the ferroelectric layer 108 and a second interface between the ferroelectric layer 108 and the second anti-ferroelectric layer 110B. The compositions of the first and second anti-ferroelectric layers 110A, 110B, and the composition of the ferroelectric layer 108 although different, are generally consistent throughout the respective layers.

In some embodiments, the change in composition across the first interface is relatively abrupt with the concentration changing from that of the first anti-ferroelectric layer 110A to that of the ferroelectric layer 108 over a relatively short first transition distance (DTa1) that is less than the thickness of either of the first anti-ferroelectric layer 110A and the ferroelectric layer 108, for example, 0.1 nm to 0.5 nm, depending on the predetermined performance specifications/targets of the particular IC device and the associated design rule set. In some embodiments, the change in composition across the second interface with the concentration changing from that of the ferroelectric layer 108 to that of the second anti-ferroelectric layer 110B over a relatively short second transition distance (DTa2) that is less than the thickness of either of the ferroelectric layer 108 and the second anti-ferroelectric layer 110B, for example, 0.1 nm to 0.5 nm. depending on the design of the particular device and the associated design rule set. In some embodiments, the first and second transition distances DTa1 and DTa2 are different, i.e., when one transition is abrupt and the other transition is stepped or gradual, and, in some embodiments, the first and second transition distances DTa1 and DTa2 are substantially identical.

In some embodiments, first anti-ferroelectric layer 110A, the ferroelectric layer 108, and the second anti-ferroelectric layer 110B each comprise a compound of hafnium, zirconium, and oxygen (HZO), but in which the zirconium concentrations of the first (CD1) and second (CD3) anti-ferroelectric layers 110A, 110B are as much as two or more times the zirconium concentration (CD2) utilized in the ferroelectric layer 112 and satisfy the expressions:

CD1>CD2 [I]

CD3>CD2 [II]

In some embodiments, the relative concentrations of the anti-ferroelectric layer(s) 110A, 110B and the ferroelectric layer 108 are selected to provide ratios of CD1:CD2 and CD3:CD2 of between 3:2 and 3:1.

Similarly, in some embodiments, the relative thicknesses of the first anti-ferroelectric layer 110A (TAFE1) and the second anti-ferroelectric layer 110B (TAFE2) and the ferroelectric layer 108 (TFE) are selected to provide ratios TAFE1:TFE of between 1:100 and 1:8 and TAFE1:TAFE2 of between 1:3 and 3:1. In some embodiments, the rate of change of the concentration at an interface between the first anti-ferroelectric layer 110A and the ferroelectric layer 108 is selected to achieve a predetermined thickness of a first transition region (TTR) to satisfy the expression:

TAFE1>TTR [III]
while in some embodiments, the rate of change of the concentration at an interface between the first anti-ferroelectric layer 110A and the ferroelectric layer 108 is selected to achieve a predetermined thickness of a first transition region (TTR) to satisfy the expression:

TAFE1<TTR [IV]

In some embodiments, the first and second anti-ferroelectric layers 110A, 110B have a Hf/Zr ratio that is within a range of 0 (i.e., ZrO2) to 0.1 (Zr-rich HZO) zirconium while the ferroelectric layer 108 has a Zr/Hf ratio within a range of 0 (HfO2) to 1 (Hf/Zr balanced 50/50 in the HZO). The noted difference in the ratios of Zr and Hf in the anti-ferroelectric layers and the ferroelectric layer are selected to provide different responses to an applied electric field in the anti-ferroelectric layer(s) and the ferroelectric layer. If the noted differences in the ratios of the Zr and Hf in the anti-ferroelectric layer(s) and the ferroelectric layer are not maintained, the responses of the layers is not sufficiently distinct and compromises the performance of the IC device. In some embodiments, the Zr % in the HZO is within 60-90% with the higher percentages of Zr achieving a more AFE-like PV. In some embodiments, ZrO2 (100% Zr) is used as an AFE buffer layer. In some embodiments, the Zr % in the deposited layer is controlled by tuning a series of ALD cycles between depositing HfO2 and depositing ZrO2 in order to achieve the target composite Zr %. In some embodiments, the concentration differences between the first and second anti-ferroelectric layers 110A, 110B and the ferroelectric layer 108 are less pronounced, but are still sufficient to prevent significant residual polarization of the anti-ferroelectric layers.

In some embodiments, first anti-ferroelectric layer 110A, the ferroelectric layer 108, and the second anti-ferroelectric layer 110B each comprise a compound of hafnium, silicon, and oxygen (HSO), but in which the silicon concentrations of the first and second anti-ferroelectric layers 110A, 110B are as much as two or more times the silicon concentration utilized in the ferroelectric layer 108. In some embodiments, the first and second anti-ferroelectric layers 110A, 110B contain up to about 5-10 atomic percent (at. %) silicon while the ferroelectric layer 108 contains only about 1-5 at. % silicon. In other embodiments, the concentration differences between the first and second anti-ferroelectric layers 110A, 110B and the ferroelectric layer 108 are less pronounced, but are still sufficient to prevent significant residual polarization of the anti-ferroelectric layers.

In some embodiments, first anti-ferroelectric layer 110A, the ferroelectric layer 108, and the second anti-ferroelectric layer 110B each comprise a compound of hafnium, silicon, zirconium, and oxygen (HSZO), but in which the silicon+zirconium concentrations of the first and second anti-ferroelectric layers 110A, 110B are as much as two or more times the silicon+zirconium concentration utilized in the ferroelectric layer 108. In some embodiments, the first and second anti-ferroelectric layers 110A, 110B contain up to about Si (~5-10 at. %) and Zr (60-90 at. %) silicon+zirconium while the ferroelectric layer 108 contains only about 1-5 at. % Si and about 40-50 at. % Zr. In other embodiments, the concentration differences between the first and second anti-ferroelectric layers 110A, 110B and the ferroelectric layer 108 are less pronounced, but are still sufficient to prevent significant residual or revenant polarization of the anti-ferroelectric layers.

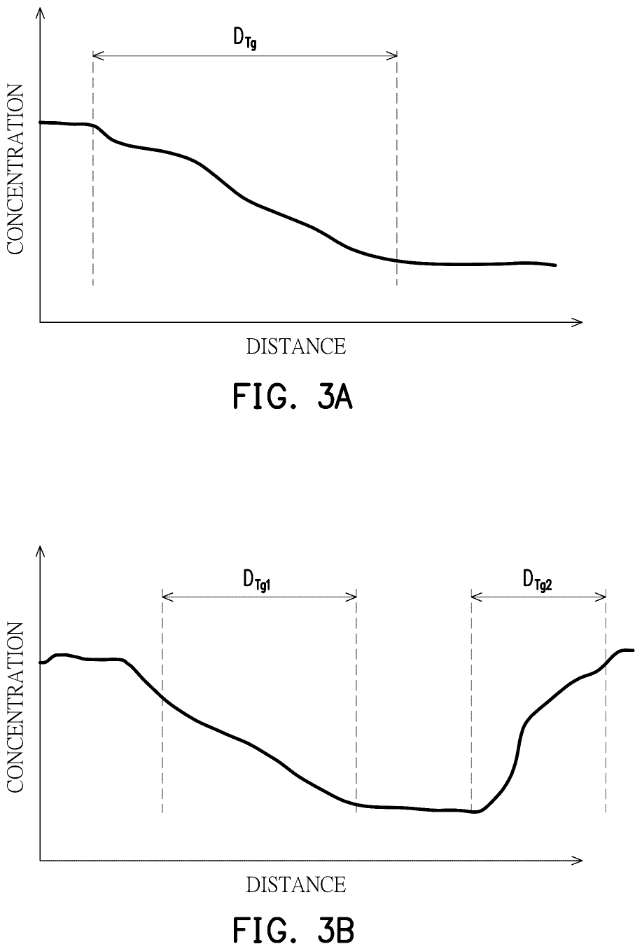

The difference in the doping levels for some embodiments is illustrated in FIG. 3A in which the composition of the first anti-ferroelectric layer 110A and the ferroelectric layer 108, although different, exhibit a tapered or gradual change of concentration across at least a portion of the respective layers. In such embodiments, the change in composition is relatively gradual with the concentration changing from that of the first anti-ferroelectric layer 110A to that of the ferroelectric layer 108 over a relatively long transition distance (DTg) that, in some embodiments, spans a majority, or a substantial minority, of the first anti-ferroelectric layer 110A and/or the ferroelectric layer 108. In some embodiments, the transition distance (DTg) is between about 0.1-0.5 nm. In some embodiments, when the transition distance (DTg) is less than about 0.1 nm, the change in composition will induce crystalline defects that will degrade the performance of the IC device. In some embodiments, when the transition distance (DTg) is more than about 0.5 nm, the interaction between the adjacent ferroelectric and anti-ferroelectric layers will be suppressed and will degrade the performance of the IC device.

The difference in the doping levels for some embodiments is illustrated in FIG. 3B in which the composition of the first anti-ferroelectric layer 110A, the ferroelectric layer 108, and the second anti-ferroelectric layer 110B, although exhibiting different compositions, show a tapered or gradual change concentration across at least a portion of the respective layers. Although the atomic ratios of the various component atoms vary across the first anti-ferroelectric layer 110A, the ferroelectric layer 108, and/or the second anti-ferroelectric layer 110B, each of the layers will be characterized or exhibit an average dopant concentration when measured across the full layer.

The first and second anti-ferroelectric layers 110A, 110B can have different or substantially identical average dopant concentrations, but both of the anti-ferroelectric layer average dopant concentrations will be greater than an average dopant concentration for the ferroelectric layer. In some embodiments, only one or two of the first anti-ferroelectric layer 110A, the ferroelectric layer 108, and the second anti-ferroelectric layer 110B a change in composition and/or dopant concentration that is relatively gradual and extends across a relatively long first transition distance (DTg1) that, in some embodiments, spans a majority, or a substantial minority, of the thicknesses of the first anti-ferroelectric layer 110A and/or the ferroelectric layer 108. In some embodiments, the concentration changing from that of the ferroelectric layer 108 to that of the second anti-ferroelectric layer 110B is relatively gradual and extends across a relatively long first transition distance (DTg2) that, in some embodiments, spans a majority, or a substantial minority of, the thicknesses of the ferroelectric layer 108 and/or the second anti-ferroelectric layer 110B. The first and second transition distances DTg1, DTg1 need not be identical and, in some embodiments in which the first and second transition distances are not substantially equal, the first and second transition distances may have a ratio of between 5:1 and 1:5. In some embodiments, the AFE layer thickness range is about 0.1-0.5 nm with the FE layer thickness range is about 5-10 nm. In some embodiments, when the AFE layer thickness is less than about 0.1 nm, the AFE layer will not provide sufficient buffering between the FE layer and adjacent materials and will degrade the performance and/or the functional lifetime of the IC device. In some embodiments, when the AFE layer thickness is more than about 0.5 nm, the additional thickness requires additional processing time without significantly improving the buffering action of the AFE layer. In some embodiments, when the FE layer thickness is less than about 5 nm, the ferroelectric function will be reduced and will degrade the performance of the IC device. In some embodiments, when the FE layer thickness is greater than about 10 nm, forming the FE layer requires additional processing time without significantly improving the ferroelectric function of the IC device.

In some embodiments, the composition of the first and/or second anti-ferroelectric layers 110A, 110B is/are selected for increasing the dielectric constant and thereby reducing potential depolarization effects in the ferroelectric layer resulting from the electrical field induced by current flowing through the metal oxide channel during device operation and/or remnant polarization in one or both of the anti-ferroelectric layers.

In some embodiments, first anti-ferroelectric layer 110A, the ferroelectric layer 108, and the second anti-ferroelectric layer 110B each comprise a compound of hafnium, silicon, and oxygen (HSO) and/or a compound of hafnium, silicon and/or zirconium, and oxygen (HSZO) with the relative concentrations of the HSO and HSZO versions corresponding to those for the HZO layers.

In some embodiments, the first anti-ferroelectric layer 110A, the ferroelectric layer 108, and the second anti-ferroelectric layer 110B (if present) have a generally uniform thickness. In some embodiments, the first and second anti-ferroelectric layers 110A, 110B, are thinner than the ferroelectric layer 108. In some embodiments, the first and second anti-ferroelectric layers 110A, 110B have a thickness of 0.1-5 nm while the ferroelectric layer 108 has a thickness range of 5-15 nm. In some embodiments, the first and second anti-ferroelectric layers 110A, 110B have a thickness of 0.1-1 nm while the ferroelectric layer 108 has a thickness range of 8-10 nm, resulting in a ratio of the thicknesses of the ferroelectric layer and the anti-ferroelectric layer(s) of between 8:1 and 100:1. In some embodiments, the thickness and/or the composition of the first anti-ferroelectric layer 110A are selected to increase the effectiveness of the anti-ferroelectric layer as a diffusion barrier between the metal oxide channel 108 and the ferroelectric layer 108 and/or to reduce interface traps at the junction between the ferroelectric layer and the metal oxide channel. Both suppressing diffusion and reducing interface traps will tend to improve the operation and reduce the failures of the resulting IC devices that incorporate this metal oxide/anti-ferroelectric/ferroelectric layer configuration.

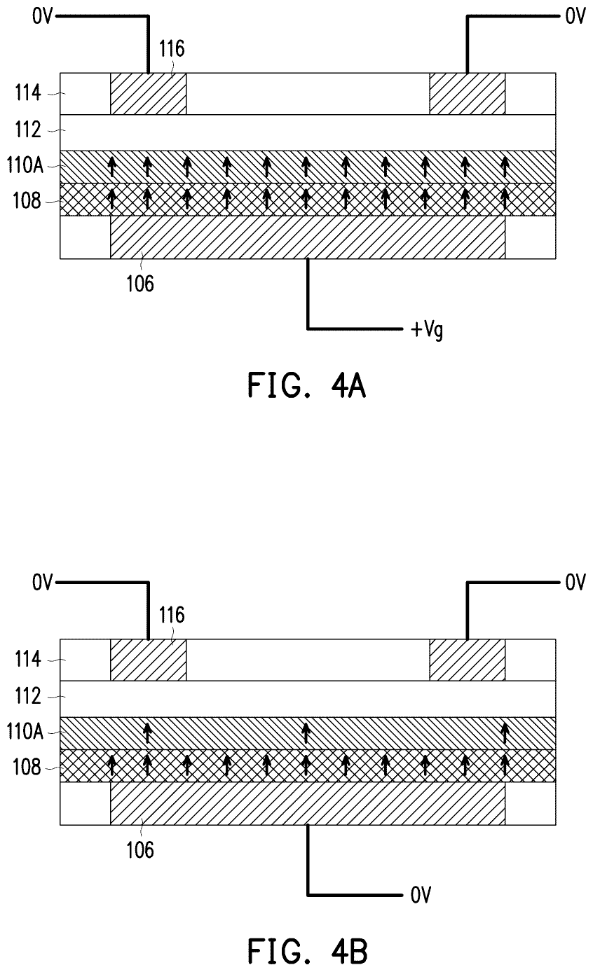

FIG. 4A is a cross-sectional view of a FeFET device structure during a programming operation. During the programming operation, a programing voltage +Vg is applied to the back gate 106 while the source and drain regions 116 are held at ground voltage (0 V). The application of the programming voltage is of sufficient magnitude and duration to induce a directional electric field which extends through the ferroelectric layer 108 and the first anti-ferroelectric layer 110A. The directional electric field causes the dipoles within the ferroelectric layer 108 to align in a direction parallel to the directional electric field.

FIG. 4B is a cross-sectional view of a FeFET device structure after a programming operation. After programming, with a ground voltage (0 V) applied to the back gate layer 114, the source and drain regions 116, the ferroelectric layer 108 maintains the polarization induced by the directional electric field during the programming operation.

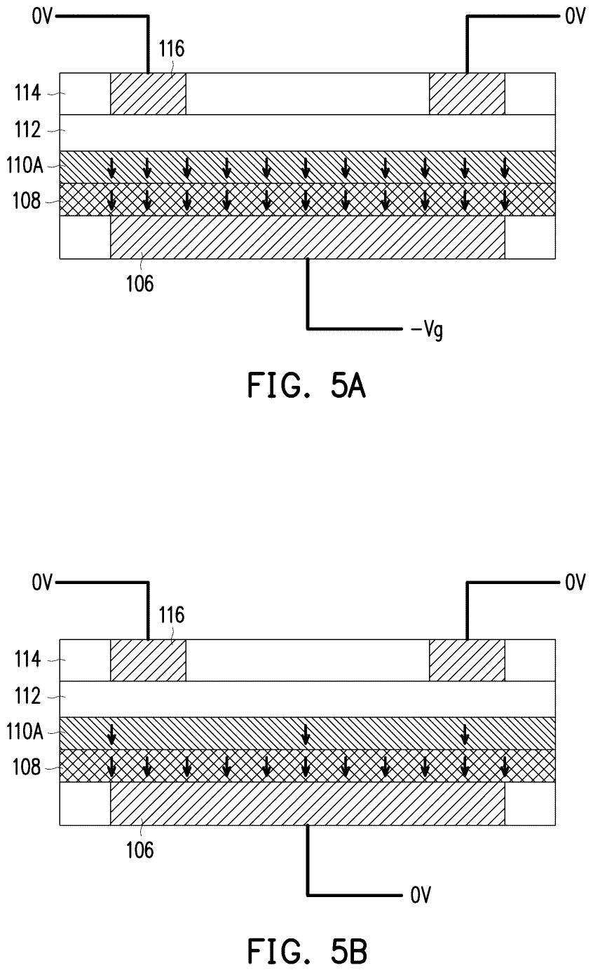

FIG. 5A is a cross-sectional view of a FeFET device structure during an erase operation. During the erase operation, an erase voltage −Vg is applied to the back gate layer 106 while the source region and drain regions 116 are held at ground voltage (0 V). The application of the erase voltage is of sufficient magnitude and duration to induce a directional electric field which extends through the ferroelectric layer 108 and the first anti-ferroelectric layer 110A. The directional electric field causes the dipoles within the ferroelectric layer 108 to align in a direction parallel to the directional electric field and opposite to the direction induced during the programming operation.

FIG. 5B is a cross-sectional view of a FeFET device structure after an erase operation has been completed. After erasure, with a ground voltage (0 V) applied to the back gate layer 106, the source and drain regions 116, the ferroelectric layer 108 maintains the polarization induced by the directional electric field during the erase operation.

Because hafnium oxide is useful as a gate insulator in high-k metal-gate (HKMG) processes, standard HKMG transistors including gate insulator that are modified to make the gate material ferroelectric, are useful in nonvolatile HKMG transistors, i.e., the FeFET.

FeFETs exhibit nonvolatile characteristics due to the fact that the two stable, remnant polarization states of the ferroelectric gate insulator or memory layer modify the threshold voltage even when supply voltage is removed. Accordingly, the binary states are encoded in the threshold voltage of the transistor.

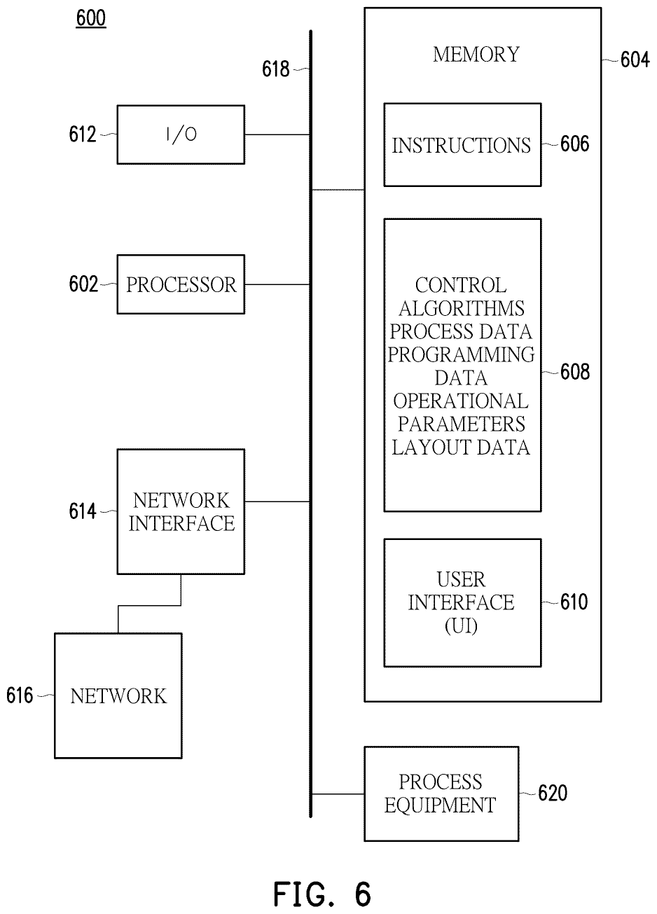

FIG. 6 is a block diagram of an electronic process control (EPC) system 600, in accordance with some embodiments. Methods used for generating cell layout diagrams corresponding to some embodiments of the FinFET structures detailed above, particularly with respect to the addition and placement of the field plate contact on the RPO structure are implementable, for example, using EPC system 600, in accordance with some embodiments of such systems. In some embodiments, EPC system 600 is a general purpose computing device including a hardware processor 602 and a non-transitory, computer-readable, storage medium 604. Computer-readable storage medium 604, amongst other things, is encoded with, i.e., stores, computer program code (or instructions) 606, i.e., a set of executable instructions. Execution of computer program code 606 by hardware processor 602 represents (at least in part) an EPC tool which implements a portion or all of, e.g., the methods described herein in accordance with one or more (hereinafter, the noted processes and/or methods).

Hardware processor 602 is electrically coupled to computer-readable storage medium 604 via a bus 618. Hardware processor 602 is also electrically coupled to an I/O interface 612 by bus 618. A network interface 614 is also electrically connected to hardware processor 602 via bus 618. Network interface 614 is connected to a network 616, so that hardware processor 602 and computer-readable storage medium 604 are capable of connecting to external elements via network 616. Hardware processor 602 is configured to execute computer program code 606 encoded in computer-readable storage medium 604 in order to cause the EPC system 600 to be usable for performing a portion or all of the noted processes and/or methods. In one or more embodiments, hardware processor 602 is a central processing unit (CPU), a multi-processor, a distributed processing system, an application specific integrated circuit (ASIC), and/or a suitable processing unit.

In one or more embodiments, computer-readable storage medium 604 is an electronic, magnetic, optical, electromagnetic, infrared, and/or a semiconductor system (or apparatus or device). For example, computer-readable storage medium 604 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 604 includes a compact disk-read only memory (CD-ROM), a compact disk-read/write (CD-R/W), and/or a digital video disc (DVD).

In one or more embodiments, computer-readable storage medium 604 stores computer program code 606 configured to cause the EPC system 600 (where such execution represents (at least in part) the EPC tool) to be usable for performing a portion or all of the noted processes and/or methods. In one or more embodiments, computer-readable storage medium 604 also stores information which facilitates performing a portion or all of the noted processes and/or methods. In one or more embodiments, computer-readable storage medium 604 stores process control data 608 including, in some embodiments, control algorithms, process variables and constants, target ranges, set points, programming control data, and code for enabling statistical process control (SPC) and/or model predictive control (MPC) based control of the various processes.

EPC system 600 includes I/O interface 612. I/O interface 612 is coupled to external circuitry. In one or more embodiments, I/O interface 612 includes a keyboard, keypad, mouse, trackball, trackpad, touchscreen, and/or cursor direction keys for communicating information and commands to hardware processor 602.

EPC system 600 also includes network interface 614 coupled to hardware processor 602. Network interface 614 allows EPC system 600 to communicate with network 616, to which one or more other computer systems are connected. Network interface 614 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more EPC systems 600.

EPC system 600 is configured to send information to and receive information from fabrication tools 620 that include one or more of ion implant tools, etching tools, deposition tools, coating tools, rinsing tools, cleaning tools, chemical-mechanical planarizing (CMP) tools, testing tools, inspection tools, transport system tools, and thermal processing tools that will perform a predetermined series of manufacturing operations to produce the desired integrated circuit devices. The information includes one or more of operational data, parametric data, test data, and functional data used for controlling, monitoring, and/or evaluating the execution, progress, and/or completion of the specific manufacturing process. The process tool information is stored in and/or retrieved from computer-readable storage medium 604.

EPC system 600 is configured to receive information through I/O interface 612. The information received through I/O interface 612 includes one or more of instructions, data, programming data, design rules that specify, e.g., layer thicknesses, spacing distances, structure and layer resistivity, and feature sizes, process performance histories, target ranges, set points, and/or other parameters for processing by hardware processor 602. The information is transferred to hardware processor 602 via bus 618. EPC system 600 is configured to receive information related to a user interface (UI) through I/O interface 612. The information is stored in computer-readable medium 604 as user interface (UI) 610.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EPC tool. In some embodiments, a portion or all of the noted processes and/or methods is implemented as a software application that is used by EPC system 600.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

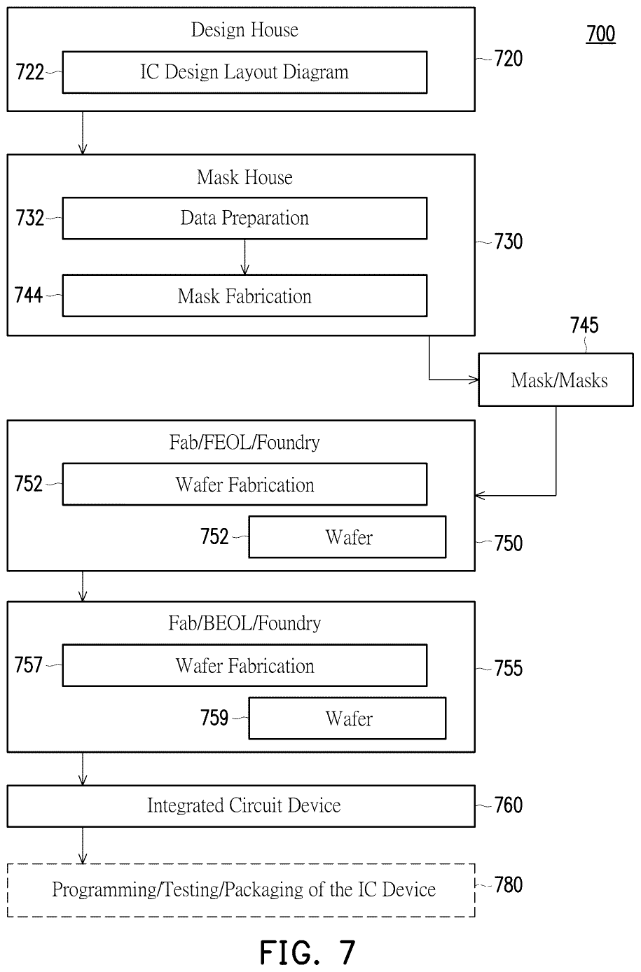

FIG. 7 is a block diagram of an integrated circuit (IC) manufacturing system 700, and an IC manufacturing flow associated therewith, in accordance with some embodiments for manufacturing IC devices that incorporate the improved control over the SSD and EPI profile. In some embodiments, based on a layout diagram, at least one of (A) one or more semiconductor masks or (B) at least one component in a layer of a semiconductor integrated circuit is fabricated using manufacturing system 700.

In FIG. 7, IC manufacturing system 700 includes entities, such as a design house 720, a mask house 730, and an IC manufacturer/fabricator (“fab”) 750, that interact with one another in the design, development, and manufacturing cycles and/or services related to manufacturing an IC device 760. Once the manufacturing process has been completed to form a plurality of IC devices on a wafer, the wafer is optionally sent to backend or back end of line (BEOL) 780 for, depending on the device, programming, electrical testing, and packaging in order to obtain the final IC device products. The entities in manufacturing system 700 are connected by a communications network. In some embodiments, the communications network is a single network. In some embodiments, the communications network is a variety of different networks, such as an intranet and the Internet.

The communications network includes wired and/or wireless communication channels. Each entity interacts with one or more of the other entities and provides services to and/or receives services from one or more of the other entities. In some embodiments, two or more of design house 720, mask house 730, and IC Fab 750 is owned by a single larger company. In some embodiments, two or more of design house 720, mask house 730, and IC Fab 750 coexist in a common facility and use common resources.

Design house (or design team) 720 generates an IC design layout diagram 722. IC design layout diagram 722 includes various geometrical patterns designed for an IC device 760. The geometrical patterns correspond to patterns of metal, oxide, or semiconductor layers that make up the various components of IC device 760 to be fabricated. The various layers combine to form various IC features.

For example, a portion of IC design layout diagram 722 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 720 implements a proper design procedure to form IC design layout diagram 722. The design procedure includes one or more of logic design, physical design or place and route. IC design layout diagram 722 is presented in one or more data files having information of the geometrical patterns. For example, IC design layout diagram 722 can be expressed in a GDSII file format or DFII file format.

Whereas the pattern of a modified IC design layout diagram is adjusted by an appropriate method in order to, for example, reduce parasitic capacitance of the integrated circuit as compared to an unmodified IC design layout diagram, the modified IC design layout diagram reflects the results of changing positions of conductive line in the layout diagram, and, in some embodiments, inserting to the IC design layout diagram, features associated with capacitive isolation structures to further reduce parasitic capacitance, as compared to IC structures having the modified IC design layout diagram without features for forming capacitive isolation structures located therein.

Mask house 730 includes mask data preparation 732 and mask fabrication 744. Mask house 730 uses IC design layout diagram 722 to manufacture one or more masks 745 to be used for fabricating the various layers of IC device 760 according to IC design layout diagram 722. Mask house 730 performs mask data preparation 732, where IC design layout diagram 722 is translated into a representative data file (“RDF”). Mask data preparation 732 provides the RDF to mask fabrication 744. Mask fabrication 744 includes a mask writer. A mask writer converts the RDF to an image on a substrate, such as a mask (reticle) 745 or a semiconductor wafer 753. The IC design layout diagram 722 is manipulated by mask data preparation 732 to comply with particular characteristics of the mask writer and/or requirements of IC Fab 750. In FIG. 7, mask data preparation 732 and mask fabrication 744 are illustrated as separate elements. In some embodiments, mask data preparation 732 and mask fabrication 744 can be collectively referred to as mask data preparation.

In some embodiments, mask data preparation 732 includes optical proximity correction (OPC) which uses lithography enhancement techniques to compensate for image errors, such as those that can arise from diffraction, interference, other process effects and the like. OPC adjusts IC design layout diagram 722. In some embodiments, mask data preparation 732 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 732 includes a mask rule checker (MRC) that checks the IC design layout diagram 722 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 722 to compensate for limitations during mask fabrication 744, which may undo part of the modifications performed by OPC in order to meet mask creation rules.

In some embodiments, mask data preparation 732 includes lithography process checking (LPC) that simulates processing that will be implemented by IC Fab 750 to fabricate IC device 760. LPC simulates this processing based on IC design layout diagram 722 to create a simulated manufactured device, such as IC device 760. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 722.

It should be understood that the above description of mask data preparation 732 has been simplified for the purposes of clarity. In some embodiments, mask data preparation 732 includes additional features such as a logic operation (LOP) to modify the IC design layout diagram 722 according to manufacturing rules. Additionally, the processes applied to IC design layout diagram 722 during mask data preparation 732 may be executed in a variety of different orders.

After mask data preparation 732 and during mask fabrication 744, a mask 745 or a group of masks 745 are fabricated based on the modified IC design layout diagram 722. In some embodiments, mask fabrication 744 includes performing one or more lithographic exposures based on IC design layout diagram 722. In some embodiments, an electron-beam (e-beam) or a mechanism of multiple e-beams is used to form a pattern on a mask (photomask or reticle) 745 based on the modified IC design layout diagram 722. Mask 745 can be formed in various technologies. In some embodiments, mask 745 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 745 includes a transparent substrate (e.g., fused quartz) and an opaque material (e.g., chromium) coated in the opaque regions of the binary mask.

In another example, mask 745 is formed using a phase shift technology. In a phase shift mask (PSM) version of mask 745, various features in the pattern formed on the phase shift mask are configured to have proper phase difference to enhance the resolution and imaging quality. In various examples, the phase shift mask can be attenuated PSM or alternating PSM. The mask(s) generated by mask fabrication 744 is used in a variety of processes. For example, such a mask(s) is used in an ion implantation process to form various doped regions in semiconductor wafer 753, in an etching process to form various etching regions in semiconductor wafer 753, and/or in other suitable processes.

IC Fab 750 includes wafer fabrication 752. IC Fab 750 is an IC fabrication business that includes one or more manufacturing facilities for the fabrication of a variety of different IC products. In some embodiments, IC Fab 750 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

Wafer fabrication 752 includes forming a patterned layer of mask material formed on a semiconductor substrate is made of a mask material that includes one or more layers of photoresist, polyimide, silicon oxide, silicon nitride (e.g., Si3N4, SiON, SiC, SiOC), or combinations thereof. In some embodiments, masks 745 include a single layer of mask material. In some embodiments, a mask 745 includes multiple layers of mask materials.

In some embodiments, the mask material is patterned by exposure to an illumination source. In some embodiments, the illumination source is an electron beam source. In some embodiments, the illumination source is a lamp that emits light. In some embodiments, the light is ultraviolet light. In some embodiments, the light is visible light. In some embodiments, the light is infrared light. In some embodiments, the illumination source emits a combination of different (UV, visible, and/or infrared) light.

Subsequent to mask patterning operations, areas not covered by the mask, e.g., fins in open areas of the pattern, are etched to modify a dimension of one or more structures within the exposed area(s). In some embodiments, the etching is performed with plasma etching, or with a liquid chemical etch solution, according to some embodiments. The chemistry of the liquid chemical etch solution includes one or more of etchants such as citric acid (C6H8O7), hydrogen peroxide (H2O2), nitric acid (HNO3), sulfuric acid (H2SO4), hydrochloric acid (HCl), acetic acid (CH3CO2H), hydrofluoric acid (HF), buffered hydrofluoric acid (BHF), phosphoric acid (H3PO4), ammonium fluoride (NH4F) potassium hydroxide (KOH), ethylenediamine pyrocatechol (EDP), TMAH (tetramethylammonium hydroxide), or a combination thereof.

In some embodiments, the etching process is a dry-etch or plasma etch process. Plasma etching of a substrate material is performed using halogen-containing reactive gasses excited by an electromagnetic field to dissociate into ions. Reactive or etchant gases include, for example, CF4, SF6, NF3, Cl2, CCl2F2, SiCl4, BCl2, or a combination thereof, although other semiconductor-material etchant gases are also envisioned within the scope of the present disclosure. Ions are accelerated to strike exposed material by alternating electromagnetic fields or by fixed bias according to methods of plasma etching that are known in the art.

In some embodiments, etching processes include presenting the exposed structures in the functional area(s) in an oxygen-containing atmosphere to oxidize an outer portion of the exposed structures, followed by a chemical trimming process such as plasma-etching or liquid chemical etching, as described above, to remove the oxidized material and leave behind a modified structure. In some embodiments, oxidation followed by chemical trimming is performed to provide greater dimensional selectivity to the exposed material and to reduce a likelihood of accidental material removal during a manufacturing process. In some embodiments, the exposed structures may include the fin structures of Fin Field Effect Transistors (FinFET) with the fins being embedded in a dielectric support medium covering the sides of the fins. In some embodiments, the exposed portions of the fins of the functional area are top surfaces and sides of the fins that are above a top surface of the dielectric support medium, where the top surface of the dielectric support medium has been recessed to a level below the top surface of the fins, but still covering a lower portion of the sides of the fins.

IC Fab 750 uses mask(s) 745 fabricated by mask house 730 to fabricate IC device 760. Thus, IC Fab 750 at least indirectly uses IC design layout diagram 722 to fabricate IC device 760. In some embodiments, semiconductor wafer 753 is fabricated by IC Fab 750 using mask(s) 745 to form IC device 760. In some embodiments, the IC fabrication includes performing one or more lithographic exposures based at least indirectly on IC design layout diagram 722. Semiconductor wafer 753 includes a silicon substrate or other proper substrate having material layers formed thereon. Semiconductor wafer 753 further includes one or more of various doped regions, dielectric features, multilevel interconnects, and the like (formed at subsequent manufacturing steps).

IC Fab 755 includes wafer fabrication 757. IC Fab 750 is an IC fabrication business that includes one or more manufacturing facilities for the continued fabrication of a variety of different IC products. In some embodiments, IC Fab 755 is a semiconductor foundry providing back end of line (BEOL) fabrication processes for forming backside structures including embodiments of the IC devices illustrated in FIGS. 1A and 1B, the interconnection and packaging of the IC products, while one or more other manufacturing facilities may provide other services for the foundry business.

Wafer fabrication 757 includes forming a patterned layer of mask material formed on a semiconductor substrate is made of a mask material that includes one or more layers of photoresist, polyimide, silicon oxide, silicon nitride (e.g., Si3N4, SiON, SiC, SiOC), or combinations thereof. In some embodiments, masks 745 include a single layer of mask material. In some embodiments, a mask 745 includes multiple layers of mask materials.

In some embodiments, the mask material is patterned by exposure to an illumination source. In some embodiments, the illumination source is an electron beam source. In some embodiments, the illumination source is a lamp that emits light. In some embodiments, the light is ultraviolet light. In some embodiments, the light is visible light. In some embodiments, the light is infrared light. In some embodiments, the illumination source emits a combination of different (UV, visible, and/or infrared) light.

Subsequent to mask patterning operations, areas not covered by the mask are etched to modify a dimension of one or more structures within the exposed area(s). In some embodiments, the etching is performed using plasma etching, reactive ion etching (RIE), or a liquid chemical etch solution, according to some embodiments. The chemistry of the liquid chemical etch solution includes one or more of etchants such as citric acid (C6H8O7), hydrogen peroxide (H2O2), nitric acid (HNO3), sulfuric acid (H2SO4), hydrochloric acid (HCl), acetic acid (CH3CO2H), hydrofluoric acid (HF), buffered hydrofluoric acid (BHF), phosphoric acid (H3PO4), ammonium fluoride (NH4F) potassium hydroxide (KOH), ethylenediamine pyrocatechol (EDP), TMAH (tetramethylammonium hydroxide), or a combination thereof.

In some embodiments, the etching process is a dry-etch or plasma etch process. Plasma etching of a substrate material is performed using halogen-containing reactive gasses excited by an electromagnetic field to dissociate into ions. Reactive or etchant gases include, for example, CF4, SF6, NF3, Cl2, CCl2F2, SiCl4, BCl2, or a combination thereof, although other semiconductor-material etchant gases are also envisioned within the scope of the present disclosure. Ions are accelerated to strike exposed material by alternating electromagnetic fields or by fixed bias according to methods of plasma etching that are known in the art.

In some embodiments, etching processes include presenting the exposed structures in the functional area(s) in an oxygen-containing atmosphere to oxidize an outer portion of the exposed structures, followed by a chemical trimming process such as plasma-etching or liquid chemical etching, as described above, to remove the oxidized material and leave behind a modified structure. In some embodiments, oxidation followed by chemical trimming is performed to provide greater dimensional selectivity to the exposed material and to reduce a likelihood of accidental material removal during a manufacturing process. In some embodiments, the exposed structures may include the structures of Ferroelectric Field Effect Transistors (FeFET) with the source and drain regions being embedded in a dielectric support medium and covered with a metal oxide channel region, a ferroelectric layer, one or more anti-ferroelectric layers, and a back gate structure.

IC Fab 755 uses mask(s) 745 fabricated by mask house 730 to fabricate IC device 760. Thus, IC Fab 755 at least indirectly uses IC design layout diagram 722 to fabricate IC device 760. In some embodiments, semiconductor wafer 759 is fabricated by IC Fab 755 using mask(s) 745 to form IC device 760. In some embodiments, the IC fabrication includes performing one or more lithographic exposures based at least indirectly on IC design layout diagram 722. Semiconductor wafer 753 includes a silicon substrate or other proper substrate having material layers formed thereon. Semiconductor wafer 759 further includes one or more of various doped regions, dielectric features, multilevel interconnects, and the like (formed during subsequent manufacturing steps).

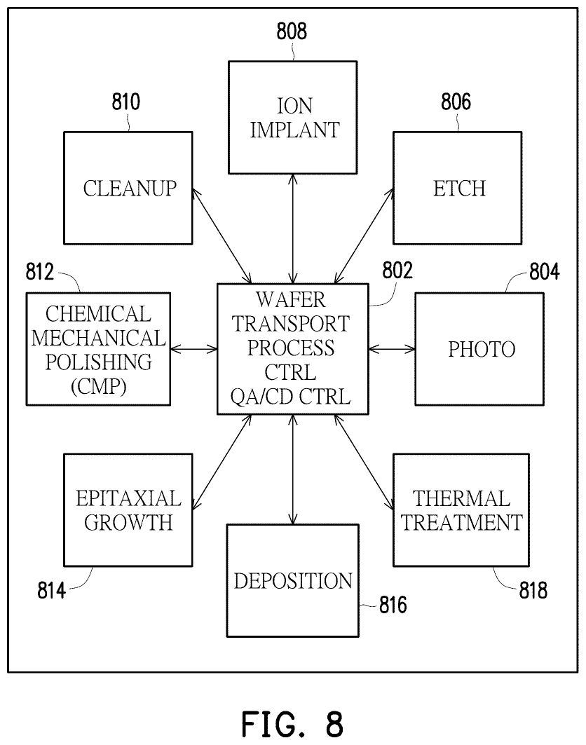

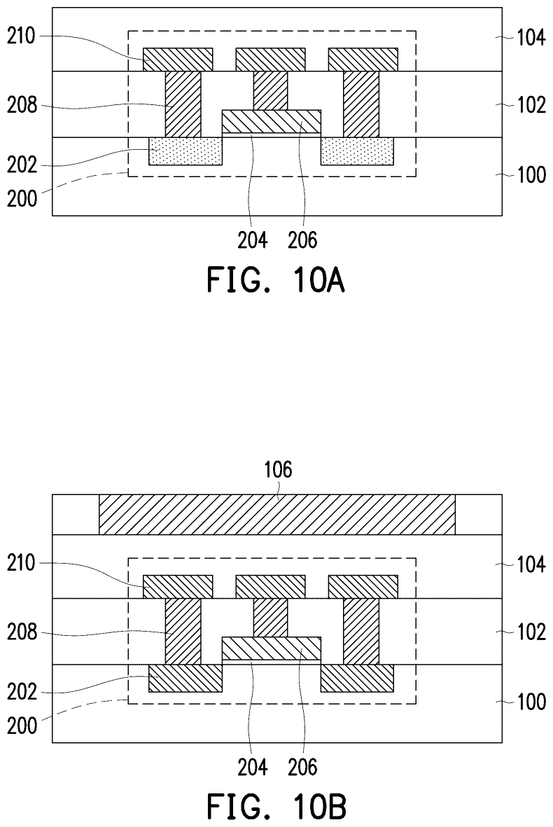

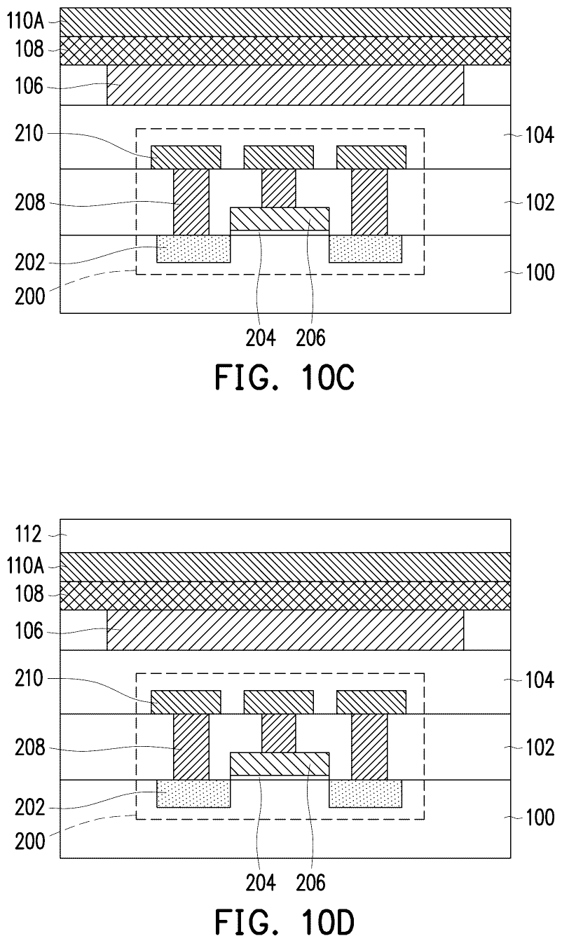

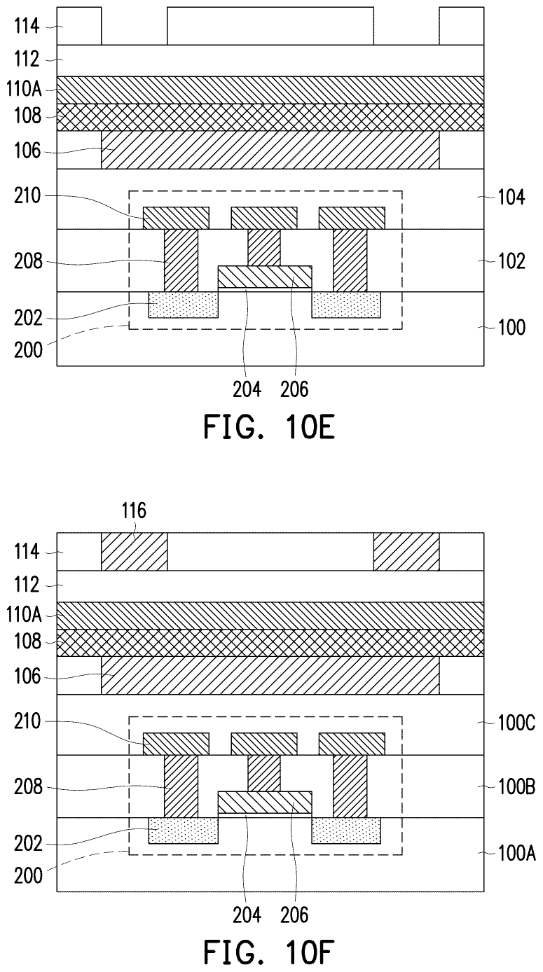

FIG. 8 is a schematic diagram of various processing departments defined within a Fab/Front End/Foundry for manufacturing IC devices according to some embodiments as suggested in FIG. 6, specifically in blocks 608 and 620 and FIG. 7, specifically in blocks 750 and 755. The processing departments utilized in both front end of line (FEOL) and back end of line (BEOL) IC device manufacturing typically include a wafer transport operation 802 for moving the wafers between the various processing departments. In some embodiments, the wafer transport operation will be integrated with an electronic process control (EPC) system according to FIG. 10 and utilized for providing process control operations, ensuring that the wafers being both processed in a timely manner and sequentially delivered to the appropriate processing departments as determined by the process flow. In some embodiments, the EPC system will also provide control and/or quality assurance and parametric data for the proper operation of the defined processing equipment. Interconnected by the wafer transport operation 802 will be the various processing departments providing, for example, photolithographic operations 804, etch operations 806, ion implant operations 808, clean-up/strip operations 810, chemical mechanical polishing (CMP) operations 812, epitaxial growth operations 814, deposition operations 816, and thermal treatments 818.

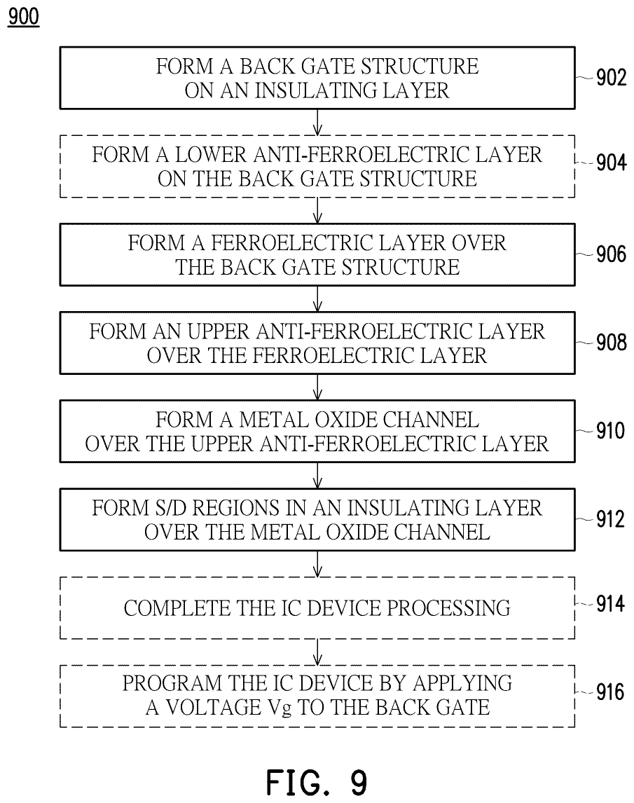

FIG. 9 is a flowchart corresponding to a series of operations utilized in some embodiments of methods 900 for manufacturing an integrated circuit.

Operation 902 includes forming a conductive back gate structure or layer over a substrate or insulating layer. The formation of a layer can be achieved using a number of processes that grow, coat, or otherwise transfer selected material(s) onto the exposed surfaces of the wafer to form a new layer on the device being manufactured. Available technologies include physical vapor deposition (PVD), chemical vapor deposition (CVD), plasma enhanced chemical vapor deposition (PECVD), electrochemical deposition (ECD), molecular beam epitaxy (MBE), and more recently, atomic layer deposition (ALD) among others. The technique selected for a particular deposition depends on factors including the process node, the type of IC being manufactured, the desired composition, uniformity, and conformity of the layer(s) and material(s) being deposited. The back gate structure or layer will subsequently be used to apply an electric field, via a programming voltage (+Vg) applied to the back gate structure, to the ferroelectric memory layer with sufficient intensity and duration to “program” the ferroelectric material and align the dipoles present in the material with the electric field. Reversing this programming by applying an erase voltage (−Vg) to the back gate structure to reverse the orientation of the “programmed” dipoles.

Optional operation 904 includes forming a lower anti-ferroelectric layer over the back gate structure for improving the interface configuration and/or performance between the back gate and the ferroelectric material(s). As with the preceding layer, the formation of a successive layer can be achieved using a number of processes that grow, coat, or otherwise transfer selected material(s) onto the exposed surfaces of the wafer to form a new layer on the device being manufactured. In some embodiments, the anti-ferroelectric material will comprise a compound containing hafnium, oxygen, and a zirconium and/or silicon dopant. The dopant(s) will be present at a concentration sufficient to suppress ferroelectric polarization behavior. In some embodiments, the dopant concentrations and/or thicknesses of the first and second anti-ferroelectric layers are similar while, in some other embodiments, the dopant concentrations and thicknesses will vary.

Operation 906 includes forming a ferroelectric layer over the back gate structure. As with the preceding layer, the formation of a successive layer can be achieved using a number of processes that grow, coat, or otherwise transfer selected material(s) onto the exposed surfaces of the wafer to form a new layer on the device being manufactured. The ferroelectric layer is capable of functioning as a memory layer that is able to be programmed by applying a programming voltage, or erased by applying an erase voltage of polarity opposite that of the programming voltage, to set an on/off condition in the metal oxide channel. In some embodiments, the ferroelectric material will comprise a compound containing hafnium, oxygen, and a zirconium and/or silicon dopant. The dopant(s) will be present at a concentration sufficient to enhance ferroelectric polarization behavior relative to that of the buffer layer(s).

Operation 908 includes forming a first or upper anti-ferroelectric layer for providing a barrier to migration of the components of the conductive channel into the ferroelectric layer and/or improving the interface configuration between the conductive channel and the anti-ferroelectric material/ferroelectric materials formed on the conductive channel. As with the preceding layer, the formation of a successive layer can be achieved using a number of processes that grow, coat, or otherwise transfer selected material(s) onto the exposed surfaces of the wafer to form a new layer on the device being manufactured. In some embodiments, the anti-ferroelectric material will comprise a compound containing hafnium, oxygen, and a zirconium and/or silicon dopant. The dopant(s) will be present at a concentration sufficient to suppress ferroelectric polarization behavior.

Operation 910 includes forming a conductive channel over the first or upper anti-ferroelectric layer. As with the preceding layer, the formation of a successive layer can be achieved using a number of processes that grow, coat, or otherwise transfer selected material(s) onto the exposed surfaces of the wafer to form a new layer on the device being manufactured. In some embodiments, the conductive channel comprises a conductive metal oxide that, under the influence of the back gate structure and/or the memory layer can selectively allow current to flow between the source and drain regions via the conductive channel.

Operation 912 includes forming source and drain (S/D) regions over the conductive channel, in which a pattern of elongated channels of N-type and/or P-type conductive material(s) are formed over different regions of the conductive channel. The source and drain regions may be formed by opening recesses in a layer of an insulating material, depositing the conductive material, and then removing the excess conductive material through an etchback or chemical-mechanical polishing (CMP) operation. Alternatively, a layer of the conductive material may be formed, patterned, and etched to provide a conductive pattern rising above the substrate with an insulating material, e.g., an interlayer dielectric (ILD), being deposited on the conductive pattern with the excess insulting material being removed through an etchback or chemical-mechanical polishing (CMP) operation.

Optional operation 914 includes completion of additional processing, testing, and/or packaging operations for making the final integrated circuit product that incorporates the combination of anti-ferroelectric and ferroelectric materials and structures previously formed on a substrate. Wafer testing is a non-destructive step performed during the semiconductor device manufacturing process. During this step, typically performed before a wafer is sent to die preparation/packaging, the integrated circuits that have been constructed on the wafer are tested for functional defects and/or performance metrics by applying a series of test patterns to the circuits. The wafer testing is typically performed on a piece of test equipment called a wafer prober (or just a probe) or tester. The wafer testing operation is referred to using several terms including, e.g., Wafer Final Test (WFT), Electronic Die Sort (EDS), and Circuit Probe (CP). In some operations, a statistical sample of the integrated circuits that passed the wafer testing routines may be pulled for additional destructive testing of, e.g., moisture resistance, ESD resistance, accelerated lifetime testing, etc., to ensure that the final integrated circuit product meets or exceeds predetermined performance goals.

Packaging is the process that connects the assembled IC with the rest of the device comprising a casing containing one or more discrete semiconductor devices or integrated circuits made up of metal, plastic, glass, or ceramic casing. Depending on the configuration, a package protects the enclosed semiconductor device(s) from overheating, radio frequency (RF) noise emissions, mechanical damage, and/or electrostatic discharge (ESD). The packaging will also include a lead frame or other conductive assembly for establishing electrical connections between external input/output elements and the contact pads provided on the semiconductor device(s). In some embodiments of IC devices, e.g., FeFETs, the gate dielectric can be programmed to be in one of two stable states. Accordingly, one of two stable binary states can be stored in the FeFETs in a manner similar to that used for programing flash memory cells. This programming operation allows the FeFET to be used as a memory or a logic transistor that maintains its logic state even after device power is removed.

Optional operation 916 includes programming of the integrated circuit device through the selective application of an electric field, via a programming voltage (+Vg) applied to the back gate structure, to the ferroelectric memory layer with sufficient intensity and duration to “program” the ferroelectric material and align the dipoles present in the material with the electric field and/or deprogramming or erasing the “programmed” regions of the ferroelectric memory layer by applying an erase voltage (−Vg) to the back gate structure to reverse the orientation of the “programmed” dipoles.

FIG. 10A is a cross-sectional view during manufacturing of a FeFET IC device according to some embodiments. In some embodiments, FIG. 10A is a cross-sectional view prior to operation 902 (FIG. 9). FIG. 10A includes a logic device 200 formed in an initial device region 102 above a semiconductor substrate 100 with a dielectric layer 104 being provided over the IC device in preparation for additional processing. Logic device 200 includes source/drain regions 202, a gate dielectric 204, a gate electrode 206, vias/contacts 208 for establishing electrical connections to the gate electrode and source/drain regions, and a metal pattern 210. According to some embodiments, the semiconductor substrate 100, initial device region 102, and dielectric layer 104 collectively comprise a substrate for the subsequent manufacture of a FeFET IC device.

FIG. 10B is a cross-sectional view during manufacturing of a FeFET IC device according to some embodiments. In some embodiments, FIG. 10B is a cross-sectional view following Operation 902 (FIG. 9) in which a back gate 106 is formed over the dielectric layer 104 provides for the formation of a conductive back gate structure or layer over a substrate or insulating layer. In some embodiments, a dielectric pattern is formed with the back gate material being deposited over the dielectric pattern after which the excess back gate material is removed to obtain the back gate 106. In some embodiments, a back gate material layer is formed, patterned, and etched to obtain the back gate 106. A layer of dielectric material is then applied over the back gate 106 and the excess dielectric material being removed to provide a planar surface for subsequent FeFET processing operations.

FIG. 10C is a cross-sectional view during manufacturing of a FeFET IC device according to some embodiments. In some embodiments, FIG. 10C is a cross-sectional view following Operation 906 (FIG. 9) during which a ferroelectric layer 108 is formed over the back gate 106 for providing a memory layer that can be programmed by applying a programming voltage applied to the back gate, or erased by applying an erase voltage of polarity opposite that of the programming voltage to the back gate to set an on/off condition in the metal oxide channel. In some embodiments, the ferroelectric material will comprise a compound containing hafnium, oxygen, and a zirconium and/or silicon dopant. The dopant(s) will be present at a concentration sufficient to enhance ferroelectric polarization behavior relative to that of the buffer layer(s).

FIG. 10C is a cross-sectional view during manufacturing of a FeFET IC device according to some embodiments. In some embodiments, FIG. 10C is a cross-sectional view following Operation 908 (FIG. 9) during which a first or upper anti-ferroelectric layer 110A is formed over the ferroelectric layer 108 to provide a barrier to migration of the components of the conductive channel into the ferroelectric layer and/or improve the interface configuration between the conductive channel and the anti-ferroelectric material/ferroelectric materials formed on the conductive channel. In some embodiments, the anti-ferroelectric material will comprise a compound containing hafnium, oxygen, and a zirconium and/or silicon dopant. The dopant(s) will be present at a concentration sufficient to suppress ferroelectric polarization behavior.

FIG. 10D is a cross-sectional view during manufacturing of a FeFET IC device according to some embodiments. In some embodiments, FIG. 10D is a cross-sectional view following Operation 910 (FIG. 10) during which a conductive channel 112 is formed over the first or upper anti-ferroelectric layer 110A. In some embodiments, the conductive channel comprises a conductive metal oxide that, under the influence of the back gate and/or the memory layer can selectively allow current to flow between the source and drain regions via the conductive channel.

FIG. 10E is a cross-sectional view during manufacturing of a FeFET IC device according to some embodiments. In some embodiments, FIG. 10E is a cross-sectional view following Operation 912 (FIG. 9) during which a dielectric pattern 114 is formed over the conductive channel 112 to define a series of elongated openings that expose predetermined regions of the conductive channel. Residual portions of the dielectric pattern 114 are left on the conductive channel 112 provide electrical isolation between adjacent source/drain regions.

FIG. 10F is a cross-sectional view during manufacturing of a FeFET IC device according to some embodiments. In some embodiments, FIG. 10F is a cross-sectional view following Operation 912 (FIG. 9) during which a layer of source/drain material (not shown) is deposited over the dielectric pattern 114. The excess source/drain material is then removed to leave the source and drain regions 116 in the openings of the dielectric pattern 114.

Aspects of this description relate to a ferroelectric field effect transistor device. The ferroelectric field effect transistor device includes a back gate structure over a substrate. The ferroelectric field effect transistor device includes a ferroelectric layer over the back gate structure. The ferroelectric field effect transistor device includes an anti-ferroelectric layer over the ferroelectric layer. The ferroelectric field effect transistor device includes a metal oxide channel over the anti-ferroelectric layer, the metal oxide channel comprising a multi-component oxide compound including at least one metal from group 12 and at least one metal from group 13. The ferroelectric field effect transistor device includes source/drain regions over the metal oxide channel. In some embodiments, the ferroelectric layer is directly on the back gate structure, and the anti-ferroelectric layer is the only anti-ferroelectric layer of the device. In some embodiments, the multi-component oxide compound comprises at least one of zinc-gallium oxide, cadmium-gallium oxide, or cadmium-indium oxide. In some embodiments, the multi-component oxide compound is present in an amorphous form. In some embodiments, the anti-ferroelectric layer comprises an ordered array of electric dipoles in which adjacent dipoles are oriented in anti-parallel directions. In some embodiments, a composition changes from that of the anti-ferroelectric layer to that of the ferroelectric layer over a transition distance of 0.01 nanometers (nm) to 0.1 nm. In some embodiments, the multi-component oxide compound is present in a single-phase crystalline state, or a mixed-phase crystalline state.

Aspects of this description relate to a ferroelectric field effect transistor device. The ferroelectric field effect transistor device includes a substrate having a logic device region. The ferroelectric field effect transistor device includes an insulating layer over the substrate. The ferroelectric field effect transistor device includes a back gate over the insulating layer. The ferroelectric field effect transistor device includes a ferroelectric layer over the back gate. The ferroelectric field effect transistor device includes an anti-ferroelectric layer over and in contact with the ferroelectric layer. The ferroelectric field effect transistor device includes a metal oxide channel over the anti-ferroelectric layer, the metal oxide channel comprising zinc-gallium oxide, cadmium-gallium oxide, or cadmium-indium oxide. The ferroelectric field effect transistor device includes a dielectric pattern over the metal oxide channel. The ferroelectric field effect transistor device includes source/drain regions in the dielectric pattern, adjacent source/drain regions being electrically separated by residual portions of the dielectric pattern. In some embodiments, the anti-ferroelectric layer has a thickness of 0.1 nanometers (nm) to 1 nm and the ferroelectric layer has a thickness of 8 nm to 10 nm. In some embodiments, the ferroelectric layer comprises a material selected from the group consisting of BaTiO3, Pb(Zr, Ti)O3, SrBi2Ta2O9, BiFeO3, Bi0.5(Na0.80K0.20)0.5(Ti1−xZrx)O3, silicon-doped HfO2, silicon-doped HfZrO2, and combinations thereof. In some embodiments, a composition changes gradually from that of the anti-ferroelectric layer to that of the ferroelectric layer over a transition distance of 0.1 nm to 0.5 nm. In some embodiments, the anti-ferroelectric layer and the ferroelectric layer each comprise a compound of hafnium, zirconium, and oxygen, and the anti-ferroelectric layer has an Hf/Zr ratio within a range of 0 to 0.1. In some embodiments, the back gate comprises a bulk conductor and at least one of a seed layer, an adhesion layer, or a barrier layer adjacent to the bulk conductor. In some embodiments, the source/drain regions extend through the dielectric pattern and contact the metal oxide channel.

Aspects of this description relate to a method of manufacturing an integrated circuit. The method includes forming a back gate structure on a substrate. The method further includes forming a ferroelectric layer and an anti-ferroelectric layer over the back gate structure in a single deposition process during which a ratio of components fed into a deposition chamber is adjusted such that the ferroelectric layer exhibits ferroelectric properties and the anti-ferroelectric layer, over the ferroelectric layer, exhibits anti-ferroelectric properties. The method further includes forming a metal oxide channel over the anti-ferroelectric layer. The method further includes forming source/drain regions over the metal oxide channel. In some embodiments, adjusting the ratio of components produces at least one step change in composition between the ferroelectric layer and the anti-ferroelectric layer. In some embodiments, adjusting the ratio of components comprises tuning a series of atomic layer deposition cycles between depositing HfO₂ and depositing ZrO₂ to achieve a target composite zirconium percentage. In some embodiments, forming the metal oxide channel comprises depositing a multi-component oxide compound including at least one metal from group 12 and at least one metal from group 13. In some embodiments, forming the anti-ferroelectric layer comprises forming the anti-ferroelectric layer to a thickness of 0.1 nanometers (nm) to 1 nm. In some embodiments, forming the source/drain regions comprises: forming a dielectric pattern over the metal oxide channel; and forming the source/drain regions in openings in the dielectric pattern such that adjacent source/drain regions are separated by residual portions of the dielectric pattern.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of some embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A ferroelectric field effect transistor device comprising:
a back gate structure over a substrate;
a ferroelectric layer over the back gate structure;
an anti-ferroelectric layer over the ferroelectric layer; and
a metal oxide channel over the anti-ferroelectric layer, the metal oxide channel comprising a multi-component oxide compound including at least one metal from group 12 and at least one metal from group 13; and
source/drain regions over the metal oxide channel.

2. The ferroelectric field effect transistor device according to claim 1, wherein the ferroelectric layer is directly on the back gate structure, and the anti-ferroelectric layer is the only anti-ferroelectric layer of the device.

3. The ferroelectric field effect transistor device according to claim 1, wherein the multi-component oxide compound comprises at least one of zinc-gallium oxide, cadmium-gallium oxide, or cadmium-indium oxide.

4. The ferroelectric field effect transistor device according to claim 1, wherein the multi-component oxide compound is present in an amorphous form.

5. The ferroelectric field effect transistor device according to claim 1, wherein the anti-ferroelectric layer comprises an ordered array of electric dipoles in which adjacent dipoles are oriented in anti-parallel directions.

6. The ferroelectric field effect transistor device according to claim 1, wherein a composition changes from that of the anti-ferroelectric layer to that of the ferroelectric layer over a transition distance of 0.01 nanometers (nm) to 0.1 nm.

7. The ferroelectric field effect transistor device according to claim 1, wherein the multi-component oxide compound is present in a single-phase crystalline state, or a mixed-phase crystalline state.

8. A ferroelectric field effect transistor device comprising:
a substrate having a logic device region;
an insulating layer over the substrate;
a back gate over the insulating layer;
a ferroelectric layer over the back gate;
an anti-ferroelectric layer over and in contact with the ferroelectric layer;
a metal oxide channel over the anti-ferroelectric layer, the metal oxide channel comprising zinc-gallium oxide, cadmium-gallium oxide, or cadmium-indium oxide;
a dielectric pattern over the metal oxide channel; and
source/drain regions in the dielectric pattern, adjacent source/drain regions being electrically separated by residual portions of the dielectric pattern.

9. The ferroelectric field effect transistor device according to claim 8, wherein the anti-ferroelectric layer has a thickness of 0.1 nanometers (nm) to 1 nm and the ferroelectric layer has a thickness of 8 nm to 10 nm.

10. The ferroelectric field effect transistor device according to claim 8, wherein the ferroelectric layer comprises a material selected from the group consisting of BaTiO₃, Pb(Zr, Ti)O₃, SrBi₂Ta₂O₉, BiFeO₃, Bi_{0.5}(Na_{0.80}K_{0.20})_{0.5}(Ti₁₋ₓZrₓ)O₃, silicon-doped HfO₂, silicon-doped HfZrO₂, and combinations thereof.

11. The ferroelectric field effect transistor device according to claim 8, wherein a composition changes gradually from that of the anti-ferroelectric layer to that of the ferroelectric layer over a transition distance of 0.1 nm to 0.5 nm.

12. The ferroelectric field effect transistor device according to claim 8, wherein the anti-ferroelectric layer and the ferroelectric layer each comprise a compound of hafnium, zirconium, and oxygen, and the anti-ferroelectric layer has an Hf/Zr ratio within a range of 0 to 0.1.

13. The ferroelectric field effect transistor device according to claim 8, wherein the back gate comprises a bulk conductor and at least one of a seed layer, an adhesion layer, or a barrier layer adjacent to the bulk conductor.

14. The ferroelectric field effect transistor device according to claim 8, wherein the source/drain regions extend through the dielectric pattern and contact the metal oxide channel.

15. A method of manufacturing an integrated circuit comprising:
forming a back gate structure on a substrate;
forming a ferroelectric layer and an anti-ferroelectric layer over the back gate structure in a single deposition process during which a ratio of components fed into a deposition chamber is adjusted such that the ferroelectric layer exhibits ferroelectric properties and the anti-ferroelectric layer, over the ferroelectric layer, exhibits anti-ferroelectric properties;
forming a metal oxide channel over the anti-ferroelectric layer; and
forming source/drain regions over the metal oxide channel.

16. The method according to claim 15, wherein adjusting the ratio of components produces at least one step change in composition between the ferroelectric layer and the anti-ferroelectric layer.

17. The method according to claim 15, wherein adjusting the ratio of components comprises tuning a series of atomic layer deposition cycles between depositing HfO₂ and depositing ZrO₂ to achieve a target composite zirconium percentage.

18. The method according to claim 15, wherein forming the metal oxide channel comprises depositing a multi-component oxide compound including at least one metal from group 12 and at least one metal from group 13.

19. The method according to claim 15, wherein forming the anti-ferroelectric layer comprises forming the anti-ferroelectric layer to a thickness of 0.1 nanometers (nm) to 1 nm.

20. The method according to claim 15, wherein forming the source/drain regions comprises:
forming a dielectric pattern over the metal oxide channel; and
forming the source/drain regions in openings in the dielectric pattern such that adjacent source/drain regions are separated by residual portions of the dielectric pattern.
